(19) United States
(12) Patent Application Publication
(10) Pub. No.: US 2003/0011362 A1
(43) Pub. Date: Jan. 16, 2003

(54) Current transformer

(76) Inventors: Thomas Gohlsch, Moosburg (DE); Christian Vetter, Kirchdorf (DE); Alexander Eigner, Munchen (DE); Franz Leitsch, Moosburg (DE)

Correspondence Address: David E. Huang, Esq., CHAPIN & HUANG, L.L.C., Westborough Office Park, 1700 West Park Drive, Westborough, MA, 01581, US

(21) Appl. No.: 10/193,491

(22) Filed: Jul. 11, 2002

(30) Foreign Application Priority Data
Jul. 12, 2001 (DE) DE101 34 014.1-35

(51) Int. Cl. G01N 27/72; G01R 33/07

(52) U.S. Cl. 324/220; 324/251

(57) ABSTRACT

The invention relates to a current transformer (1) for measurement and protection purposes in high- or medium-voltage power supply networks which include busbars guided in support insulators, which current transformer is characterized in that a busbar (3) is surrounded, in the range of the head (21) of a support insulator (2), in a spaced-apart relation by a non-closed ring (4) of magnetically conductive material which is arranged within the material of the support insulator (2); that the magnetic field sensor (5) is arranged, also within the material of the support insulator (2), in the gap between the open ends of the ring (4); and that the connecting leads (6) of the magnetic field sensor (5) are guided through the body (22) of the support insulator (2) as far as the base (23) thereof and are capable of being tapped there. Thus in accordance with the invention a current transformer (1) is furnished which may be realized with a small structural size and particularly with the dimensions of a support insulator. It may thus at the same time assume the supporting function of a support insulator. In addition it delivers low-power measurement signals suited for direct further processing by a relay or the like.

### CROSS REFERENCE TO RELATED APPLICATIONS

This application claims the benefit of priority to German Application No. DE 101 34 014.1-35, filed Jul. 12, 2001 and entitled “Stromwandler,” the teachings of which are hereby incorporated by reference in their entirety.

### FIELD OF THE INVENTION

The present invention relates, in general, to electrical transformers, and more particularly to a current transformer for measurement and protection in high- to medium-voltage power supply networks which include busbars guided in support insulators.

### BACKGROUND OF THE INVENTION

A current transformer detects the current carried on a line network in order to measure power consumption or to protect connected components against energy spikes, i.e., the current transformer is designed as a measuring or protection transformer. Customarily, a voltage measuring transformer is additionally provided for this purpose, wherein a measuring apparatus or a relay is supplied with the measured current or voltage values, respectively. This measuring apparatus or relay then determines, based on the measured values, whether or not inadmissibly high power is being carried on the network and prevents damage to connected electrical components by disrupting the connection whenever this is necessary.

The current transformers traditionally used heretofore were constructed in accordance with the transformer principle, i.e., such a current transformer includes primary and secondary windings, with a current in proportion with the lead current being generated in the secondary winding. The resulting outputs are then received by the relay and utilized for evaluation of a current network load capability.

### SUMMARY OF THE INVENTION

It is an essential drawback of these known current transformers of the conventional transformer type that they possess a considerable structural size and a corresponding weight. Their handling during installation accordingly is not favorable, while they additionally occupy valuable construction space particularly under restricted spatial conditions. In addition, such current transformers of the conventional transformer type deliver relatively high signal outputs that are too high for recent generations of relays. The outputs of such measuring transformers are therefore suitably reduced in power by correspondingly adapting the transformer assembly, however this brings about an increase of the structural size, or else these outputs are eliminated unused at a position upstream of the relay, with only the desired input power being supplied to the relay.

The invention therefore is based on the object of providing a current transformer for measurement and protection purposes in high- to medium-voltage power supply networks, which has its structural size clearly reduced in comparison with the prior art.

This object is attained through a current transformer that is characterized in particular in that a busbar is surrounded, in the range of the head of a support insulator, in a spaced-apart relation by a non-closed ring of magnetically conductive material which is arranged within the material of the support insulator; in that a magnetic field sensor is arranged, also within the material of the support insulator, in the gap between the open ends of the ring; and in that the connecting leads of the magnetic field sensor are guided through the body of the support insulator as far as the base thereof and may be tapped there.

Thus in accordance with the invention, a design of a current transformer is for the first time proposed which is capable of being integrated into a body having the form of a support insulator. Besides having a particularly compact design, it concurrently realizes the further advantage that the connecting leads of the magnetic field sensor are tapped at a sufficient isolation gap from the busbar due to the inherently available length of the support insulator, whereby a mutual influence may be excluded.

At the same time, the current transformer which in accordance with the invention is integrated in a support insulator body, does not differ or only insignificantly differs from conventional support insulators in terms of shape, so that it may equally assume the customary function of supporting the busbar. The current transformer of the invention thus combines the functionality of a conventional support insulator with the measuring function for the current carried on the busbar.

Due to the small-size design of the current transformer and in particular its shape which is comparable with that of a conventional support insulator, installation of the current transformer of the invention is moreover simplified substantially.

It is a further advantage that despite the high current to be measured, the magnetic field sensor of the invention delivers a low-power signal which may in general be processed directly by a relay arranged downstream or by corresponding measuring means. Further steps for adapting the signals to the downstream measuring means etc. are thus not necessary.

The current transformer of the invention is moreover characterized by its high dielectric strength. In particular the risk of any partial discharges between the ring and the busbar is precluded because the ring does not rest directly on the busbar. Partial discharges, on the other hand, might result in destruction of the current transformer. In this regard, the design according to the invention provides a first isolation gap between the busbar and the ring and a second isolation gap between the ring and the magnetic field sensor. At suitable geometrical dimensioning, direct spark-over between the busbar and the magnetic field sensor may thus be avoided reliably.

Although a current transformer similar in terms of the measurement principle is already known, in the case of that current transformer a magnetically soft yet electrically not conductive core directly contacts a primary winding on the high-voltage side. The core is formed in a ring shape and not closed such that in the gap existing between the ends, a magnetic field-dependent sensor is arranged whereby a signal analogous to the carried current may be detected. As the ring-shaped core in this known construction directly contacts the primary winding, their shapes must accurately be adapted to each other so as to prevent air from being trapped during casting in casting resin which, in turn, would strongly impair the dielectric strength with a view to partial discharges. The manufacturing expense for this known current transformer consequently is high. In this construction, there moreover exists only one isolation gap between the primary winding and the sensor, for the core, due to its material properties, remains out of consideration with regard to the electrical properties of the current transformer. There is no known disclosure about the location and the fashion of arranging this current transformer in a high- to medium-voltage power supply network. In particular, known prior art does not provide any hints that a like current transformer might also be realized within the dimensions of a support insulator while making use of the accompanying additional advantages.

Advantageous developments of the invention result from the features of the subclaims.

The magnetic field sensor thus is preferably designed as a Hall effect sensor inasmuch as the latter delivers a signal across a large bandwidth which is well suited for use by downstream measuring means. A Hall effect sensor moreover detects any applied current intensities in a same manner, for as it does not include an iron core, a saturation effect accordingly does not occur. In addition it is therefore possible to revert to well-tried measuring means.

It is furthermore possible for the support insulator to be screw-connected at the base—in a manner known per se—with a support rail, with the connecting lead of the magnetic field sensor intended for grounding being electrically connected with the screw socket in the support insulator that is provided for the screw connection. Grounding of the current transformer is hereby achieved in a particularly simple manner as regards construction. This further reduces the installation expense.

It is furthermore advantageous if the connecting leads for the signals from the magnetic field sensor may be tapped in a lateral position at the base of the support insulator at a 90-degree angle with the orientation of the busbar. In such a case an interaction between the tapping locations and the busbar carrying a high voltage may be prevented even more reliably. Reliability of the assembly is thereby increased even further.

If the ring is dimensioned such that magnetic saturation will not occur in the range of measurement of the magnetic field sensor, the scope of possible applications and the reliability of the current transformer of the invention will be improved further.

It is furthermore advantageous if the spacing of the ring from the busbar is selected as a function of the network load capability and of the dielectric properties of the material for the support insulator. As a result, the structural size of the current transformer can be kept within the required limits without performance and reliability of the current transformer being worsened.

### BRIEF DESCRIPTION OF THE DRAWINGS

The foregoing and other objects, features and advantages of the invention will be apparent from the following description of particular embodiments of the invention, as illustrated in the accompanying drawings in which like reference characters refer to the same parts throughout the different views.

FIG. 1 is a schematic front view of a current transformer of the invention; and

FIG. 2 is a lateral view of the current transformer of the invention.

### DETAILED DESCRIPTION

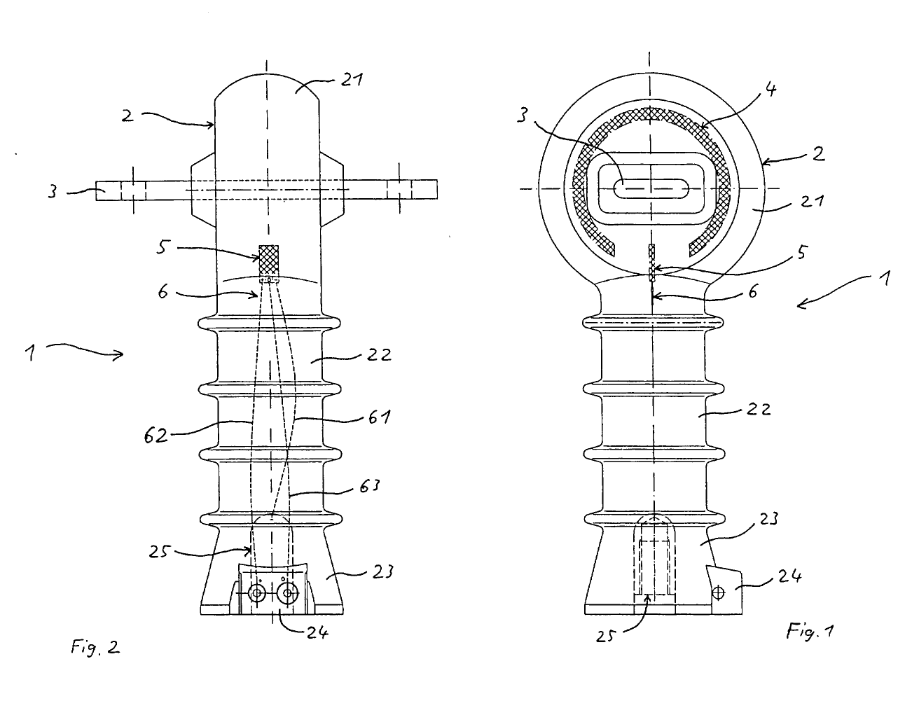

In accordance with the representations in FIGS. 1 and 2, a current transformer 1 includes a body having the form of a support insulator 2 having a head 21, a body 22 and a base 23. Through the head 21 of the support insulator 2, a busbar 3 is guided. The busbar is positioned within the electrically insulating material of the support insulator 2. Around the busbar 3, in a spaced-apart relation, also within the material of the support insulator 2, a ring 4 of magnetically conductive material is arranged. The ring 4 is indicated schematically by cross-hatching. As the ring 4 does not directly contact the busbar 3, it can also be formed of electrically conductive material. The distance between the busbar 3 and the ring 4 is determined as a function of the network voltage carried on the busbar 3, and of the dielectric properties of the material of the support insulator 2 which generally is epoxy resin.

In the manner visible from FIG. 1, the ring 4 is not closed, with a gap accordingly existing between the open ends of the ring 4. In this gap, a magnetic field sensor 5 is arranged which has the form of a Hall effect sensor in this embodiment. Connecting leads 6 lead away from magnetic field sensor 5, with a grounding lead 61 and two signal lines 62 and 63 being shown in FIG. 2. The connecting leads 6 are cast in the support insulator 2 and thus immobilized in it, and are routed from the region of the head having the ring 4 and the magnetic field-dependent sensor 5 arranged therein, through the body 22 as far as the base 23 of the support insulator 2. It therefore is not necessary to observe a particular routing path for the connecting leads 6.

On the base 23, a connection socket 24 is formed with two ports which are connected to the two signal lines 62 and 63. The connection socket 24 laterally points away from the principal axis of the support insulator 2 while having an arrangement staggered by 90 degrees from the orientation of the busbar 3. The grounding lead 61 is moreover connected to a screw socket 25 that is embedded concentrically with the center axis of the support insulator 2 at the bottom side of the base 23. The screw socket 25 allows for direct fastening of the support insulator 2 to a support rail (not represented here) or the like, and at the same time establishes a grounding connection.

The entire measurement sensory mechanism and the derivations are dimensioned and arranged, respectively, in accordance with the dielectric requirements and cast in the synthetic resin of the support insulator 2. The current transformer 1 thus has the form of an integral body that has a shape similar to that of a conventional support insulator which does not have a measuring function. The head 21 of the support insulator has only the busbar 3, the ring 4, the magnetic field sensor 5 and the connecting leads 6, i.e., no further metallic elements that might impair the function of the current transformer 1 are present in the head 21.

To the end of carrying out the current measurement, the current transformer 1 is tied in with a line network, i.e., current-carrying rails are connected to the busbar 3, e.g. by screw connection. The current carried on the busbar 3 generates a magnetic field in proportion with the flow of current, which magnetic field is bundled by the ring 4. The ring 4 directs this magnetic field to the magnetic field sensor 5 located in the gap, and this sensor delivers an output signal that is proportional with the magnetic field and consequently with the current. This output signal is carried via the connecting leads 6 to the connection socket 24 and may be tapped there for being supplied to a relay or the like.

In this embodiment, the busbar 3 having a rectangular cross-section is furthermore provided with rounded edges in the range of the head 21, so that corona or corona discharges are avoided. The partial discharge onset voltage is clearly reduced hereby. In the present embodiment, the rounded edges of the busbar 3 are produced by a finishing step. In addition it is also possible to employ a busbar having a round cross-section which will, however, typically have a lower tensile strength than the busbar 3 of the invention which is made of flat metal.

In another embodiment, depressions or through holes may moreover be formed centrally in the busbar, which permit the casting resin to flow in or flow through during the pressing process in the course of manufacturing the support insulator 2. This serves to achieve an additional fixation of the busbar after the casting resin has cured. Application of unilateral loads and any desired mounting positions of the current transformer 1 are thus made possible. In addition, this also serves as a countermeasure against a risk of the busbar being pulled out from the head of the support insulator. This manner of positional fixation or anchoring moreover provides a permanently identical position of the busbar relative to the magnetic field sensor and results in improved accuracy of measurement.

The invention thus furnishes a current transformer 1 for measurement and protection purposes in high- to medium-voltage power supply networks which include busbars guided in support insulators, wherein the busbar 3 is surrounded, in the range of the head 21 of the support insulator 2, in a spaced-apart relation by a non-closed ring 4 of magnetically conductive material which is arranged within the material of the support insulator 2, with the magnetic field sensor 5 being arranged, also within the material of the support insulator 2, in the gap between the open ends of the ring 4, and with the connecting leads 6 of the magnetic field sensor 5 being guided through the body 22 of the support insulator 2 as far as the base 23 thereof and being capable of being tapped there. Hereby a current transformer 1 is furnished which may be realized with a small structural size and in particular with the dimensions of a support insulator. It may thus at the same time assume the support function of a support insulator. In addition it delivers low-power measurement signals suited for direct further processing by a relay or the like.

It is to be understood that the above-described embodiments are simply illustrative of the principles of the invention. Various and other modifications and changes may be made by those skilled in the art which will embody the principles of the invention and fall within the spirit and scope thereof.

What is claimed is:

1. A current transformer for measurement and protection purposes in high- to medium-voltage power supply networks which include busbars guided in support insulators, the current transformer comprising:
a support insulator having a head, a body, and a non-closed ring of magnetically conductive material which is arranged within the material of said support insulator;
a busbar, wherein at least a portion of the busbar is surrounded, in a range of the head of the support insulator, in a spaced-apart relation by the non-closed ring of magnetically conductive material which is arranged within the material of said support insulator; and
a magnetic field sensor having connecting leads, wherein the magnetic field sensor is arranged within the material of the support insulator, in a gap between the open ends of said non-closed ring, and wherein the connecting leads of said magnetic field sensor are guided through said body of said support insulator as far as a base of the body to enable tapping there.

2. The current transformer of claim 1 wherein said magnetic field sensor is a Hall effect sensor.

3. The current transformer of claim 2 wherein said support insulator is screw-connected at said base with a support rail, and wherein a connecting lead intended for grounding said magnetic field sensor is electrically connected with a screw socket provided for screw connection in said support insulator.

4. The current transformer of claim 3 wherein said connecting leads of said magnetic field sensor are configured to be tapped laterally on said base of said support insulator at an angle of 90 degrees relative to the orientation of said busbar.

5. The current transformer of claim 4 wherein said non-closed ring is dimensioned such that magnetic saturation does not occur in the range of measurement of said magnetic field sensor.

6. The current transformer of claim 5 wherein a distance of said non-closed ring from said busbar is selected as a function of network load capability and dielectric properties of the material of the support insulator.

7. The current transformer of claim 4 wherein a distance of said non-closed ring from said busbar is selected as a function of network load capability and dielectric properties of the material of the support insulator.

8. The current transformer of claim 3 wherein said non-closed ring is dimensioned such that magnetic saturation does not occur in the range of measurement of said magnetic field sensor.

9. The current transformer of claim 8 wherein a distance of said non-closed ring from said busbar is selected as a function of network load capability and dielectric properties of the material of the support insulator.

10. The current transformer of claim 3 wherein a distance of said non-closed ring from said busbar is selected as a function of network load capability and dielectric properties of the material of the support insulator.

11. The current transformer of claim 2 wherein said connecting leads of said magnetic field sensor are configured to be tapped laterally on said base of said support insulator at an angle of 90 degrees relative to the orientation of said busbar.

12. The current transformer of claim 11 wherein said non-closed ring is dimensioned such that magnetic saturation does not occur in the range of measurement of said magnetic field sensor.

13. The current transformer of claim 12 wherein a distance of said non-closed ring from said busbar is selected as a function of network load capability and dielectric properties of the material of the support insulator.

14. The current transformer of claim 11 wherein a distance of said non-closed ring from said busbar is selected as a function of network load capability and dielectric properties of the material of the support insulator.

15. The current transformer of claim 2 wherein said non-closed ring is dimensioned such that magnetic saturation does not occur in the range of measurement of said magnetic field sensor.

16. The current transformer of claim 15 wherein a distance of said non-closed ring from said busbar is selected as a function of network load capability and dielectric properties of the material of the support insulator.

17. The current transformer of claim 2 wherein a distance of said non-closed ring from said busbar is selected as a function of network load capability and dielectric properties of the material of the support insulator.

18. The current transformer of claim 1 wherein said support insulator is screw-connected at said base with a support rail, and wherein a connecting lead intended for grounding said magnetic field sensor is electrically connected with a screw socket provided for screw connection in said support insulator.

19. The current transformer of claim 18 wherein said connecting leads of said magnetic field sensor are configured to be tapped laterally on said base of said support insulator at an angle of 90 degrees relative to the orientation of said busbar.

20. The current transformer of claim 19 wherein said non-closed ring is dimensioned such that magnetic saturation does not occur in the range of measurement of said magnetic field sensor.

21. The current transformer of claim 20 wherein a distance of said non-closed ring from said busbar is selected as a function of network load capability and dielectric properties of the material of the support insulator.

22. The current transformer of claim 19 wherein a distance of said non-closed ring from said busbar is selected as a function of network load capability and dielectric properties of the material of the support insulator.

23. The current transformer of claim 18, wherein said non-closed ring is dimensioned such that magnetic saturation does not occur in the range of measurement of said magnetic field sensor.

24. The current transformer of claim 23 wherein a distance of said non-closed ring from said busbar is selected as a function of network load capability and dielectric properties of the material of the support insulator.

25. The current transformer of claim 18 wherein a distance of said non-closed ring from said busbar is selected as a function of network load capability and dielectric properties of the material of the support insulator.

26. The current transformer of claim 1 wherein said connecting leads of said magnetic field sensor are configured to be tapped laterally on said base of said support insulator at an angle of 90 degrees relative to the orientation of said busbar.

27. The current transformer of claim 26, wherein said non-closed ring is dimensioned such that magnetic saturation does not occur in the range of measurement of said magnetic field sensor.

28. The current transformer of claim 27 wherein a distance of said non-closed ring from said busbar is selected as a function of network load capability and dielectric properties of the material of the support insulator.

29. The current transformer of claim 26 wherein a distance of said non-closed ring from said busbar is selected as a function of network load capability and dielectric properties of the material of the support insulator.

30. The current transformer of claim 1, wherein said non-closed ring is dimensioned such that magnetic saturation does not occur in the range of measurement of said magnetic field sensor.

31. The current transformer of claim 30 wherein a distance of said non-closed ring from said busbar is selected as a function of network load capability and dielectric properties of the material of the support insulator.

32. The current transformer of claim 1 wherein a distance of said non-closed ring from said busbar is selected as a function of network load capability and dielectric properties of the material of the support insulator.
